(19) United States
(12) Patent Application Publication
(10) Pub. No.: US 2004/0012092 A1
(43) Pub. Date: Jan. 22, 2004

(54) Apparatus and method for reducing interference between signal lines

(76) Inventors: Paul John Schwab, Hudson, NH (US); Andrew Kenneth Freeston, Amherst, NH (US)

Correspondence Address: Tyco Technology Resources, Suite 450, 4550 New Linden Hill Road, Wilmington, DE, 19808-2952, US

(21) Appl. No.: 10/200,093

(22) Filed: Jul. 19, 2002

(51) Int. Cl. H01L 23/48

(52) U.S. Cl. 257/776; 438/280

(57) ABSTRACT

An integrated circuit including a first signal line disposed on a semiconductor substrate, a second signal line disposed on a first dielectric layer, the first dielectric layer disposed on the semiconductor substrate, a third signal line disposed on a second dielectric layer, the second dielectric layer disposed on the first dielectric layer, and at least two vias connecting the first signal line to the second signal line, wherein the second signal line does not span the region directly beneath the third signal line, and wherein at least a portion of the first signal line extends into the region directly beneath the third signal line.

### FIELD OF THE INVENTION

The present invention relates to the field of semiconductor devices, and more particularly to a low capacitance high frequency crossover junction for reducing interference or crosstalk.

### BACKGROUND OF THE INVENTION

One of the considerations when routing high frequency (e.g., radiofrequency (RF)) signals on an integrated circuit substrate is the crossover points of the high frequency lines. These crossover points create parasitic capacitances therebetween which causes ‘crosstalk’ of the high frequency signals from one line to another line. The crosstalk phenomenon is especially detrimental in the case of switching matrix applications which require high isolation between high frequency ports.

FIG. 1 shows a top plan view of a conventional high frequency crossover junction 100. The junction includes a first signal line 110 and a second signal line 120. The signal lines 110, 120 are preferably formed of a conductive metal (e.g., Copper), but may be formed of any conductive material. Moreover, the signal lines 110, 120 are typically disposed on separate dielectric layers 150, 160, respectively (See FIG. 2). A crossover area or region 130 exists between the first and second signal lines 110, 120 in the area directly below signal line 110 and directly above signal line 120 where the signal lines cross each other.

As shown in FIG. 2, the first signal line 110 is preferably formed on a first surface of a first dielectric layer 150. The second signal line 120 is formed on a first surface of a second dielectric layer 160. It will be noted the second dielectric layer 160 is formed on a first surface of a semiconductor substrate 170. Also formed on the semiconductor substrate 170 is a third signal line 140. The third signal line 140 may be formed of either metal or polysilicon. The first and second dielectric layers are preferably formed of Silicon Nitride (Si₃N₄) or Silicon Dioxide (SiO₂), but may be formed of any suitable dielectric.

In operation, the first signal line 110 forms a first plate of a parasitic capacitor and the second signal line forms a second plate of the parasitic capacitor in the crossover area 130. The parasitic capacitance created by the interaction of the first and second signal lines 110, 120 causes crosstalk between the first signal line 110 and the second signal line 120. Since the parasitic capacitance created by the first and second signal lines 110, 120 is inversely proportional to the distance between the signal lines, increasing the distance between the signal lines will serve to reduce the parasitic capacitance and crosstalk.

Therefore, from the above it is clear that there is presently a need for a method and apparatus for reducing parasitic capacitance between high frequency lines, thereby reducing crosstalk.

### SUMMARY OF THE INVENTION

An integrated circuit comprising a first signal line disposed on a semiconductor substrate, a second signal line disposed on a first dielectric layer, the first dielectric layer disposed on the semiconductor substrate, a third signal line disposed on a second dielectric layer, the second dielectric layer disposed on the first dielectric layer, and at least two vias connecting the first signal line to the second signal line, wherein the second signal line does not span the region directly beneath the third signal line, and wherein at least a portion of the first signal line extends into the region directly beneath the third signal line. Preferably, the second signal line does not extend into the region directly beneath the third signal line, and the first signal line spans the region directly beneath the third signal line.

A crossover junction for permitting signal lines having propagation paths to cross over the respective paths with reduced interference, comprising: a first signal line disposed on a semiconductor substrate; a second signal line disposed on a first dielectric layer, the first dielectric layer disposed on the semiconductor substrate; a third signal line disposed on a second dielectric layer, the second dielectric layer disposed on the first dielectric layer; and at least two vias connecting the first signal line to the second signal line, wherein the second signal line does not span the region directly beneath the third signal line, and wherein at least a portion of the first signal line extends into the region directly beneath the third signal line.

In a semiconductor device having first and second signal lines separated from one another by at least one dielectric layer, a method for reducing interference between signal lines, comprises the steps of: disposing a first portion of the first signal line on a substrate such that the first portion of the first signal line is separated in height from the second signal line by a greater distance than that of the distance between a second portion of the first signal line and the second signal line; and, coupling the first portion of the first signal line to the second portion of the first signal line.

### BRIEF DESCRIPTION OF THE DRAWINGS

FIG. 1 shows a top plan view of a conventional crossover junction.

FIG. 2 shows a cross sectional view of the conventional crossover junction shown in FIG. 1.

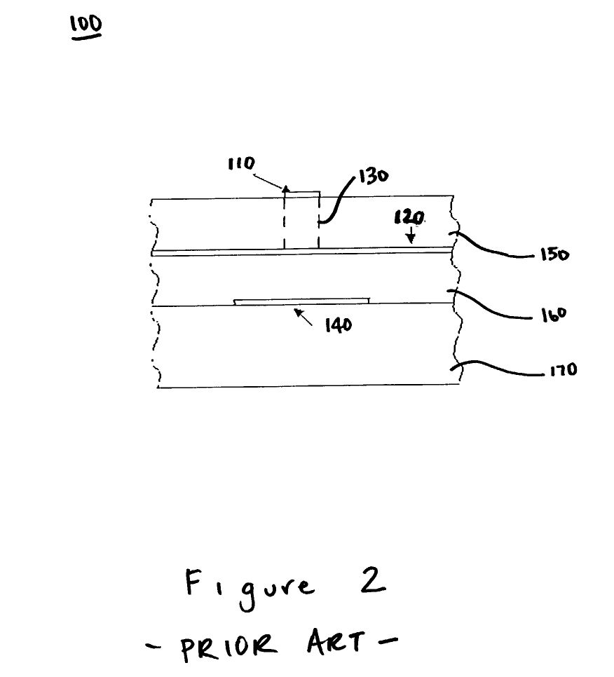

FIG. 3 shows a cross sectional view of a crossover junction according to a first exemplary embodiment of the present invention.

FIG. 4 shows an isometric view of a capacitor structure such as the type formed in the present invention.

### DETAILED DESCRIPTION OF THE INVENTION

The present invention comprises a method and apparatus for substantially reducing crosstalk interference between high frequency lines. By increasing the distance between the high frequency lines, the parasitic capacitance between the lines is reduced, as is the crosstalk.

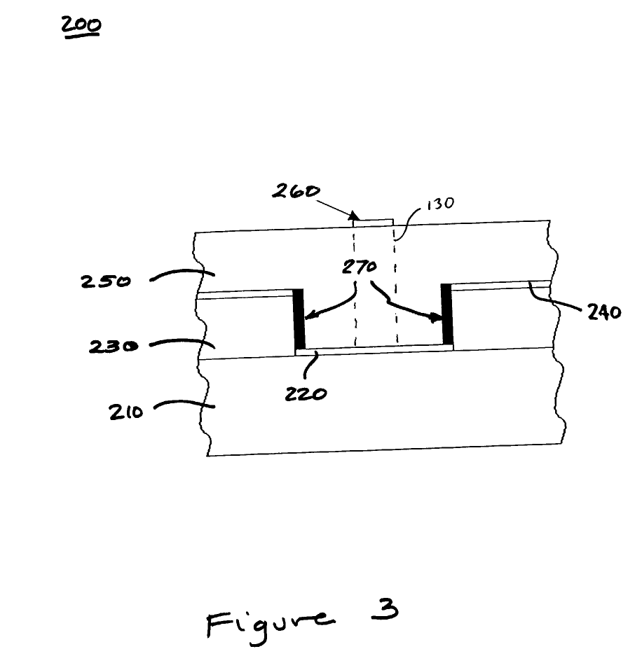

Referring now to FIG. 3, there is shown a crossover junction 200 according to a first exemplary embodiment of the present invention. The junction 200 includes a semiconductor substrate 210 with a first signal line 220 formed thereon, a first dielectric layer 230 with a second signal line 240 formed thereon, and a second dielectric layer 250 with a third signal line 260 formed thereon. A pair of vias 270 electrically couple the first signal line 220 to the second signal line 240.

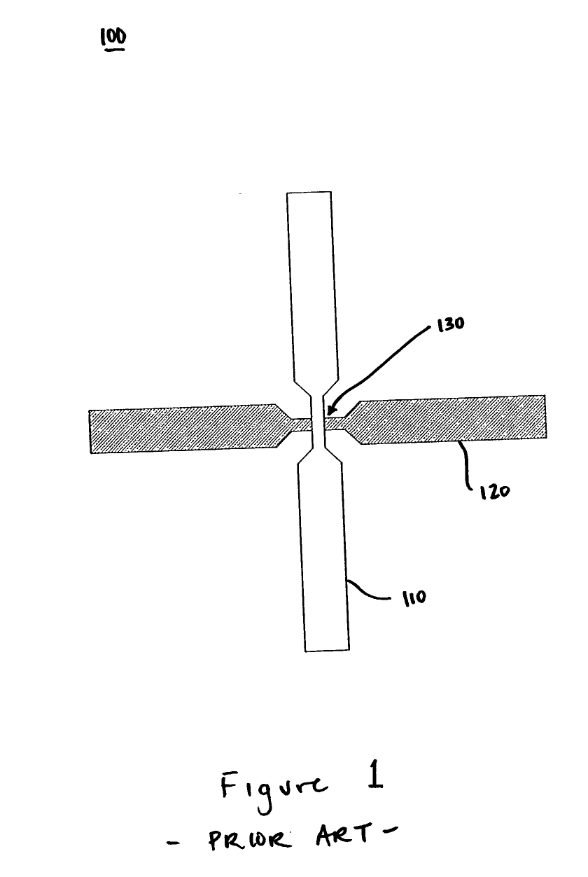

It will be noted that the second signal line 240 is not continuous across a first surface of the dielectric layer 230, as was the case in the conventional crossover junction 100 (See FIGS. 1 & 2). Thus, the second signal line 240 does not span the region 130 directly beneath signal line 110. Instead, a first signal line 220 is electrically coupled to the second signal line 240 by vias 270. In the exemplary embodiment illustrated in FIG. 3, the second signal line does not even extend into the region directly beneath the third signal line, and the first signal line 220 spans the region directly beneath the third signal line 260. Such a construction moves the second signal line 240 farther away from the third signal line 260, thus increasing the distance between the ‘plates’ of the parasitic capacitor.

Those of ordinary skill in the art will realize that the signals lines 220 and 240 may be of any suitable length and thickness. The present invention contemplates signal lines 220, 240 which are separated by distances of 500 Angstroms (Å) (0.00000197 inches) to 0.25 inches. Although greater distances between signal lines may be employed without departing from the scope of the present invention, the capacitance at such distances becomes less of a factor. Moreover, lesser distances between signal lines (e.g., less than 500 Å) may be achievable as thinner dielectric layers are fabricated without departing from the scope of the present invention.

The following formula may be used to calculate the capacitance of the parasitic capacitor created by the signal lines at the crossover area (e.g., area 130 in FIG. 1).

C=(e*L*W)/D,

where e=the dielectric constant of the dielectric layers (e.g., 230, 250; FIG. 3), L=the length of the metal crossover, W=width of the metal crossover, and D=distance between the plates (e.g., 220, 260). It will be noted by those skilled in the art that if dielectric layers 230, 250 are formed of different dielectrics, the dielectric constant ‘e’ will be the product of e₂₃₀ and e₂₅₀.

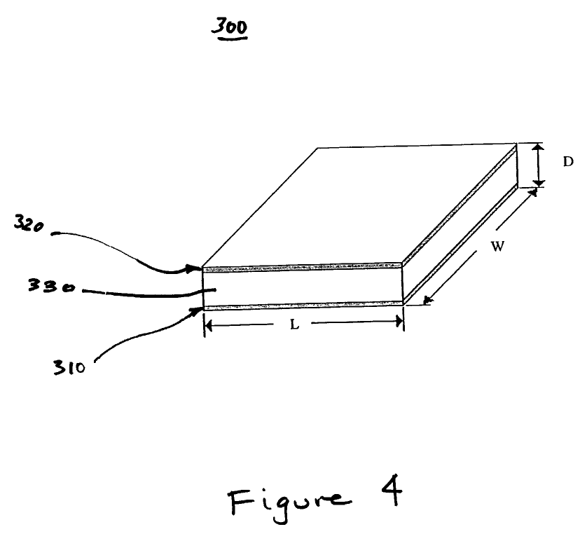

FIG. 4 shows a capacitor structure 300 including a first plate 310, a second plate 320 and a dielectric 330. As will be understood by those skilled in the art, the first and second plates 310, 320 have a specified length “L” and width “W”, and are separated by a distance “D.” In the crossover junction 200 discussed above, first signal line 220 acts as the first plate of the capacitor structure 300 (e.g., plate 310), and third signal line 260 acts as the second plate of the capacitor structure (e.g., plate 320). Similarly, the portions of dielectric layers 230 and 250 between the first and third signal lines 220 and 260 form the dielectric 330 of the capacitor structure 300. Thus, it will be noted that by increasing the distance “D” between the first and second signal lines 220 and 260, the capacitance of the crossover junction may be significantly decreased. Moreover, by decreasing the length “L” and width “W” of the respective signal lines 220 and 260, the capacitance of the crossover junction may also be decreased.

By moving a portion of one of the signal lines (e.g., 260) of the crossover junction 200 away from the other of the signal lines (e.g., 220), parasitic capacitance, and thus crosstalk, are significantly reduced.

For integrated circuits with more than three (3) conductive layers, the distance between plates (D) becomes larger, thereby improving the overall performance of the device. Once the capacitance of the individual crossovers is determined, the total number of crossovers should be determined, and their effect compensated.

While the foregoing invention has been described with reference to the above embodiments, various modifications and changes can be made without departing from the spirit of the invention. Accordingly, all such modifications and changes are considered to be within the scope of the appended claims.

What is claimed is:

1. An integrated circuit comprising:
a first signal line disposed on a semiconductor substrate;
a second signal line disposed on a first dielectric layer, said first dielectric layer disposed on said semiconductor substrate;
a third signal line disposed on a second dielectric layer, said second dielectric layer disposed on said first dielectric layer; and
at least two vias connecting the first signal line to the second signal line,
wherein said second signal line does not span the region directly beneath the third signal line, and wherein at least a portion of the first signal line extends into the region directly beneath the third signal line.

2. The integrated circuit of claim 1, wherein the second signal line does not extend into the region directly beneath the third signal line.

3. The integrated circuit of claim 1, wherein the first signal line spans the region directly beneath the third signal line.

4. The integrated circuit of claim 1, wherein a distance between the first and third signal lines is less than 0.25 inches.

5. The integrated circuit of claim 1, wherein a distance between the first and third signal lines is greater than 500 Angstroms.

6. The integrated circuit of claim 1, wherein the first and second dielectric layers are formed of a first material with a first dielectric constant.

7. The integrated circuit of claim 1, wherein the first and second dielectric layers are formed of different materials having different dielectric constants.

8. A crossover junction for permitting signal lines having propagation paths to cross over the respective paths with reduced interference, comprising:
a first signal line disposed on a semiconductor substrate;
a second signal line disposed on a first dielectric layer, said first dielectric layer disposed on said semiconductor substrate;
a third signal line disposed on a second dielectric layer, said second dielectric layer disposed on said first dielectric layer; and
at least two vias connecting the first signal line to the second signal line,
wherein said second signal line does not span the region directly beneath the third signal line, and wherein at least a portion of the first signal line extends into the region directly beneath the third signal line.

9. The crossover junction of claim 8, wherein the second signal line does not extend into the region directly beneath the third signal line.

10. The crossover junction of claim 8, wherein the first signal line spans the region directly beneath the third signal line.

11. The crossover junction of claim 8, wherein a distance between the first and third signal lines is less than 0.25 inches.

12. The crossover junction of claim 8, wherein a distance between the first and third signal lines is greater than 500 Angstroms.

13. The crossover junction of claim 8, wherein the first and second dielectric layers are formed of a first material with a first dielectric constant.

14. The crossover junction of claim 8, wherein the first and second dielectric layers are formed of different materials having different dielectric constants.

15. In a semiconductor device having first and second signal lines separated from one another by at least one dielectric layer, a method for reducing interference between signal lines, comprising the steps of:
disposing a first portion of the first signal line on a substrate such that the first portion of the first signal line is separated in height from the second signal line by a greater distance than that of the distance between a second portion of the first signal line and the second signal line; and,
coupling the first portion of the first signal line to the second portion of the first signal line.

16. The method of claim 15, wherein the step of coupling the first portion of the first signal line to the second portion of the first signal line comprises coupling the first portion of the first signal line to the second portion of the first signal line utilizing at least one via.

17. The method of claim 15, wherein the distance between the first portion of the first signal line and the second signal line is less than 0.25 inches.

18. The method of claim 15, wherein the distance between the first portion of the first signal line and the second signal line is greater than 500 Angstroms.
